(19) United States
(12) Patent Application Publication
(10) Pub. No.: US 2025/0047195 A1
(43) Pub. Date: Feb. 6, 2025

(54) POWER CONVERSION UNIT DIAGNOSIS SYSTEM

(71) Applicant: HITACHI, LTD., Tokyo (JP)

(72) Inventors: Hiroshi KAMIZUMA, Tokyo (JP); Takae SHIMADA, Tokyo (JP); Kimihisa FURUKAWA, Tokyo (JP); Yuki KAWAGUCHI, Tokyo (JP); Yuuichi MABUCHI, Tokyo (JP)

(21) Appl. No.: 18/842,831

(22) PCT Filed: Jan. 6, 2023
(86) PCT No.: PCT/JP2023/000151

§ 371 Date: Aug. 30, 2024

(30) Foreign Application Priority Data
Mar. 15, 2022 (JP) 2022-040501

(51) Int. Cl. H02M 1/32; H02M 1/00; H02M 7/12

(52) U.S. Cl. CPC H02M 1/327; H02M 1/007; H02M 7/12

(57) ABSTRACT

The power conversion unit diagnosis system has: a plurality of power conversion units that supply the DC power to at least one load and are connected in series with each other; a control unit that controls the plurality of power conversion units; and an output side switching unit that enables the output portions of at least some of the plurality of power conversion units to be connected in parallel with one load. When the output portions of at least some of the plurality of power conversion units are connected in parallel with the one load, the control unit determines the state of each of the plurality of power conversion units and diagnoses, on the basis of the state, whether the characteristics of each of the plurality of power conversion units are degraded or not.

### TECHNICAL FIELD

The present invention relates to a system for diagnosing a state of a power conversion unit.

### BACKGROUND ART

In recent years, power conversion units that convert alternating current (AC) into direct current (DC) or DC into AC have been used often. In addition, in applications of a high-voltage drive, an EV charger, and an electric motor, a multi-port power conversion technology has been developed in which a plurality of power conversion units are connected to a plurality of loads and operated.

In a system using a plurality of power conversion units, it is necessary to ascertain the state of each power conversion unit in order to ensure a stable output and to quickly respond when a failure occurs in some power conversion units.

PTL 1 relates to a system using a plurality of power conversion units. In the disaster prevention system described in PTL 1, it is described that a switching unit capable of switching a power supply path from a voltage conversion unit to a power supply path from an external power supply device via an external connection unit when the voltage conversion unit fails is provided in order to perform quick temporary recovery from a failure of a power supply unit.

### CITATION LIST

### Patent Literature

PTL 1: JP 2021-168593 A

### SUMMARY OF INVENTION

### Technical Problem

However, the technique described in PTL 1 relates to a measure after a failure occurs in the power supply unit, and does not describe preventing the failure of the power supply unit in advance and extending the life time of the power supply unit.

In particular, in the multi-port power conversion technology as described above, in a case where the multi-port power conversion technology is used in, for example, a charger, the number of parallel connections of the units is switched according to the number of power sources to be simultaneously charged and the capacity of each of the power sources. The life time of the unit depends on each load condition (load current/current fluctuation and ambient temperature). When the number of load fluctuations or the operation time is biased or there are initial manufacturing variations in some units, the life time of the unit is shortened. Therefore, in order to extend the life time of the unit, it is required to ascertain a deterioration state of the unit and perform operation control to suppress deterioration.

### Solution to Problem

In order to solve the above problems, a power conversion unit diagnosis system according to the present invention includes: a plurality of power conversion units each of which includes an input unit that receives alternating-current (AC) power from an AC power supply, and an output unit that converts the AC power into direct-current (DC) power and outputs the DC power, supplies the DC power to at least one load, and each of the plurality of power conversion units being connected in series to the AC power supply; a control unit that controls the plurality of power conversion units; and an output-side switching unit capable of connecting the output units of at least some of the plurality of power conversion units among the plurality of power conversion units to one of the loads in parallel, wherein the control unit determines a state of each of the plurality of power conversion units when the output units of the at least some of the plurality of power conversion units are connected in parallel to the one load and compares the determined states of the plurality of power conversion units to diagnose whether or not the characteristics of each of the plurality of power conversion units have deteriorated.

### Advantageous Effects of Invention

According to the present invention, in a case where a plurality of power conversion units are operated simultaneously, it is possible to individually determine each characteristic change. Therefore, it is possible to appropriately adjust the control of the deteriorated unit based on the characteristic change and to extend the life time of the unit.

Further features related to the present invention will become apparent from the description of the present specification and the accompanying drawings. Problems, configurations, and effects other than those described above will be clarified by the following description of embodiments.

### BRIEF DESCRIPTION OF DRAWINGS

FIG. 1 is a block diagram illustrating an outline of a power conversion unit diagnosis system according to an embodiment of the present invention.

FIG. 2 is a flowchart illustrating diagnostic processing of a power conversion unit performed using a power conversion unit diagnosis system.

FIG. 3 is a diagram illustrating an example of a method of controlling a power conversion unit performed by a control unit.

FIG. 4 is a block diagram illustrating an outline of a power conversion unit diagnosis system according to another embodiment of the present invention.

FIG. 5 is a flowchart illustrating another example of diagnostic processing performed using the power conversion unit diagnosis system.

### DESCRIPTION OF EMBODIMENTS

Hereinafter, embodiments will be described with reference to the drawings.

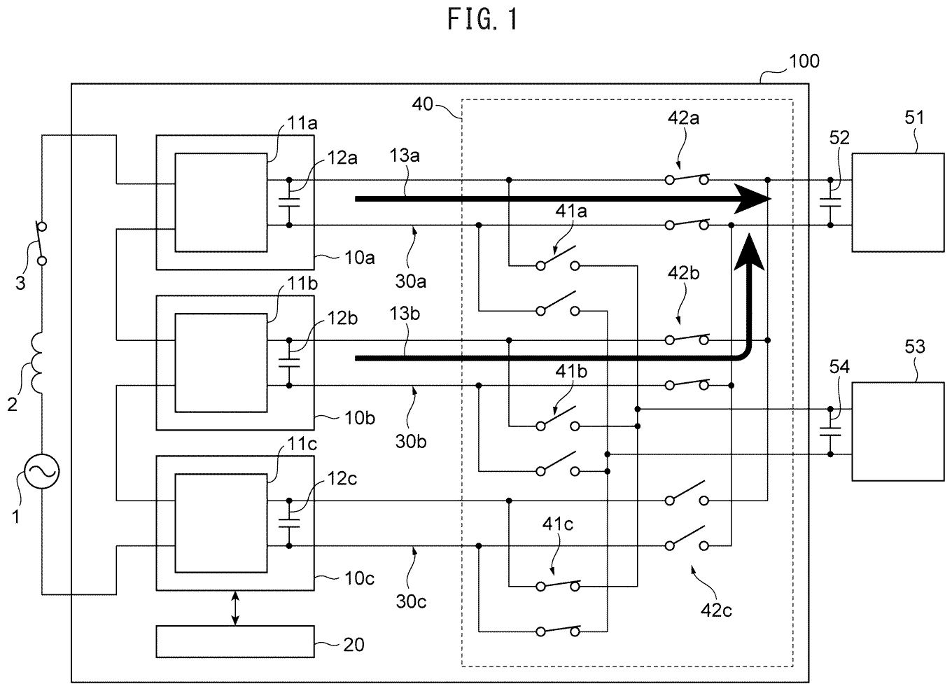

FIG. 1 is a block diagram illustrating an outline of a power conversion unit diagnosis system 100 (hereinafter, simply referred to as a “system 100”) according to an embodiment of the present invention.

The system 100 includes a plurality of power conversion units 10a to 10c whose inputs are connected to the AC power supply 1 and connected to each other in series, a power conversion unit controller 20 that determines a state of each power conversion unit and diagnoses a deterioration state of the power conversion unit based on the state, DC buses 30a to 30c connected between an output of each power conversion unit and each load, and an output-side switching unit 40 that switches connection of the DC buses. Note that, hereinafter, for simplification of description, the power conversion units 10a to 10c will be collectively referred to as a power conversion unit 10 unless otherwise specified. The same applies to other components.

An AC reactor 2 for power supply coordination, power factor improvement, and harmonic suppression, and a switching element 3 for switching connection between the AC power supply 1 and the power conversion unit 10 are provided between the AC power supply 1 and the power conversion unit 10.

Further, the output of the power conversion unit 10 is selectively connected to loads 51 and 53 by the output-side switching unit 40. The loads 51 and 53 are, for example, EV chargers or electric motors, and each outputs specific load power. Note that reference numerals 52 and 54 also represent smoothing capacitors.

Each of the power conversion units 10 includes a power semiconductor element 11 and a smoothing capacitor 12. The power semiconductor element 11 includes, for example, a metal-oxide-semiconductor field-effect transistor (MOSFET), an insulated gate bipolar transistor (IGBT), a bipolar transistor, a diode, and the like, and converts AC power input from the AC power supply 1 into DC power. The smoothing capacitor 12 converts the fluctuating DC voltage converted by the power semiconductor element 11 into a stable DC voltage.

The power conversion unit controller 20 is implemented in a computer connected to the power conversion unit 10 in a wired or wireless manner, for example, and executes processing to be described below using a CPU and a memory built in the computer.

The connection of the DC bus 30 provided between the output of the power conversion unit 10 and the loads 51 and 53 is switched by the output-side switching unit 40. As the switching elements 41 and 42 constituting the output-side switching unit 40, a mechanical switch, a semiconductor switch, or the like can be arbitrarily adopted.

In the present embodiment, the switching elements 41 and 42 constituting the output-side switching unit 40 are configured to switch the connection between one of the power conversion units 10 and one of the loads 51 and 53 by turning on/off the switching elements 41 and 42.

Specifically, the connections between the power conversion units 10a to 10c and the load 51 are switched by turning on/off the switching elements 42a to 42c, respectively, and the connections between the power conversion units 10a to 10c and the load 53 are switched by turning on/off the switching elements 41a to 41c, respectively.

In FIG. 1, since the switching elements 42a, 42b, and 41c are on, the power conversion units 10a and 10b are connected to the same load 51 (see currents 13a and 13b). The power conversion unit 10c is connected to the load 53.

That is, in the present embodiment, since the power conversion units 10a and 10b are connected to the same load 51, load power applied to the power semiconductor elements 11a and 11b and the smoothing capacitors 12a and 12b therein is also the same. Therefore, it is possible to diagnose the deterioration state of each power conversion unit by determining the states of these elements and comparing and analyzing the states among the units. Then, when there is a deviation in the operation conditions among the power conversion units, it is also possible to adjust the operation status of the power conversion unit in a direction in which the deviation is eliminated.

The states handled in the present invention are the thermal resistance of the power semiconductor element and the temperature of the smoothing capacitor. These characteristics are directly connected to deterioration of the power conversion unit and can be easily measured using an existing temperature sensor or the like, and thus are suitable as parameters for determining a deterioration state of the power conversion unit.

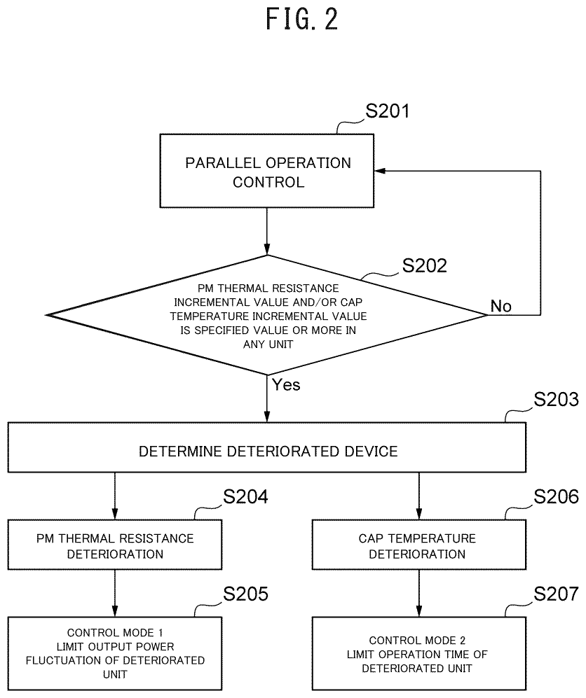

FIG. 2 is a flowchart illustrating processing performed by the power conversion unit diagnosis system 100 according to the present embodiment. First, in step S201, as illustrated in FIG. 1, a plurality of power conversion units 10 are connected in parallel to one load, and the operation is controlled. At the same time, the power conversion unit controller 20 acquires state values indicating the states of the plurality of power conversion units 10 that are connected in parallel and operated. Note that the power conversion unit controller 20 may acquire the state value, for example, when the power conversion unit 10 to be diagnosed is connected in parallel to the load, or may continue to acquire the state value during operation.

Then, in step S202, it is determined whether or not an incremental value of the thermal resistance of the power module (PM: power semiconductor element) and/or an incremental value of the temperature of the capacitor (CAP: smoothing capacitor) of any unit has reached a specified value or more.

In the case of “No” in step S202, the process returns to step S201 to continue the parallel operation. In the case of “Yes” in step S202, the process proceeds to step S203, and it is determined which element of which unit has deteriorated.

When the deteriorated element is the power semiconductor element 11 of any of the power conversion units 10 (step S204), the process proceeds to step S205, and control for suppressing deterioration of the power semiconductor element 11 is performed. When the deteriorated element is the smoothing capacitor 12 of any of the power conversion units 10 (step S206), the process proceeds to step S207, and control is performed to suppress deterioration of the smoothing capacitor 12. Note that, in a case where the control is performed once, the control is continuously performed until the operation of the power conversion unit 10 is terminated.

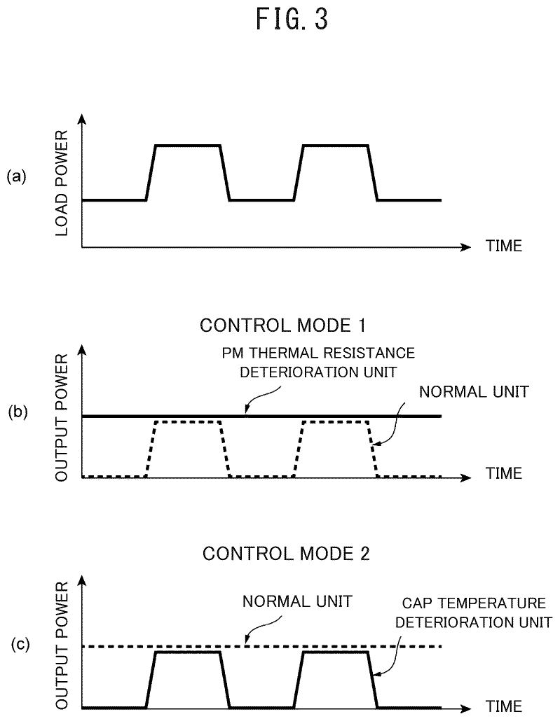

The processing for suppressing the deterioration of the element will be described with reference to FIG. 3. FIG. 3 (a) illustrates load power output from a load to which a plurality of power conversion units to be diagnosed in the processing of FIG. 2 are connected in parallel.

In step S205 in FIG. 2, that is, in a case where the deteriorated element is the power semiconductor element 11, control of a control mode 1 illustrated in FIG. 3 (b) is performed. Specifically, a signal to be supplied to the power semiconductor element 11 is controlled so that the power output from the power conversion unit 10 including the power semiconductor element 11 determined to have deteriorated becomes constant (to reduce the fluctuation range of the power). This is because the deterioration of the thermal resistance characteristic of the power semiconductor element 11 is caused by the fluctuation of the output voltage.

In step S207 in FIG. 2, that is, when the deteriorated element is the smoothing capacitor 12, control in a control mode 2 illustrated in FIG. 3 (c) is performed. Specifically, a time during which the power conversion unit 10 including the smoothing capacitor 12 determined to have deteriorated is not operated is set, and a time during which power is not output from the unit is set. This is because the degradation of the temperature of the smoothing capacitor 12 is caused by the power output.

In the present embodiment, the plurality of power conversion units 10 are connected in parallel to a single load to be in the same operation state, and then the control is performed as described above, so that it is possible to compare the state changes of the elements between the power conversion units 10, and it is possible to determine the deterioration state of each power conversion unit 10 on the basis of the comparison. In addition, the control signal is adjusted according to the deterioration state to suppress the thermal resistance deterioration of the power semiconductor element 11 and/or the temperature deterioration of the smoothing capacitor 12, and the imbalance of the operation environment occurring between the power conversion units 10 can also be resolved.

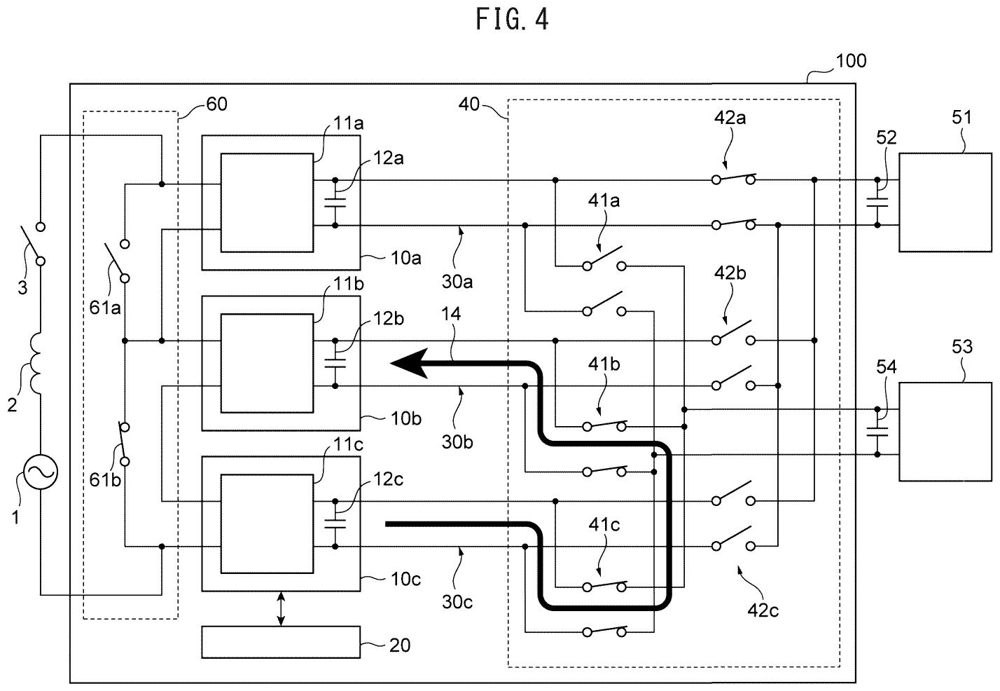

Next, a power conversion unit diagnosis system according to another embodiment of the present invention will be described with reference to FIG. 4. The system 100 illustrated in FIG. 4 differs from the system 100 illustrated in FIG. 1 in that the system 100 illustrated in FIG. 4 has, on the input side of each power conversion unit 10, an input-side switching unit 60 for switching the parallel connection between the inputs of each power conversion unit 10.

The input-side switching unit 60 includes switching elements 61a and 61b. When the switching element 61a is in the ON state, the power conversion units 10a and 10b are connected in parallel. When the switching element 61b is in the ON state, the power conversion units 10b and 10c are connected in parallel. When both of the switching elements 61a and 61b are in the ON state, all of the power conversion units 10a, 10b, and 10c are connected in parallel.

In FIG. 4, only the switching element 61b is in the ON state, and thus the power conversion units 10b and 10c are connected in parallel. The switching element 3 in the AC circuit is in the OFF state, and therefore the AC power supply 1 is not connected to the power conversion unit. In addition, in the output-side switching unit 40, the switching elements 41b and 41c are in an ON state, and thus the outputs of the power conversion units 10b and 10c are connected to the load 53.

Here, in the present embodiment, the load 53 is a storage battery.

With the above configuration, a current as indicated by an arrow 14 in FIG. 4 flows between the power conversion units 10b and 10c connected in parallel using the storage battery 53 as a power supply.

Also at this time, by executing a flow similar to that in FIG. 2, it is possible to determine the deterioration state of each power conversion unit 10 and to control the operation so as to suppress the deterioration of the element.

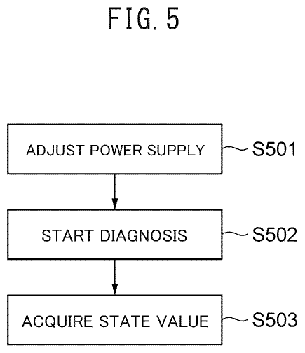

Furthermore, in the system 100 according to the present embodiment, the flow illustrated in FIG. 5 is executed. First, in step S501, the power supply is adjusted in order to set the output of the load (storage battery) to which the power conversion unit 10 is connected to a range suitable for diagnosis of the power conversion unit 10.

After the adjustment is completed, the process proceeds to step S502, the power conversion units 10 to be diagnosed are connected in parallel, and diagnosis is started. Then, the power conversion unit controller 20 acquires the state value of each power conversion unit 10 (step S503). Thereafter, processing similar to that in FIG. 2 is executed to diagnose a deterioration state of the power conversion unit 10.

As described above, in the present embodiment, since it is not necessary to operate the AC power supply 1, it is possible to diagnose the state of the unit in a self-contained manner when it is not necessary to supply power to another load 51 (for example, at night when a factory in which the load 51 is installed does not operate, or the like), which is preferable in terms of efficiency and cost.

In addition, unlike the example of FIG. 1, in the present embodiment, the power conversion units to be diagnosed can be arbitrarily combined. Therefore, it is possible to ensure completeness of diagnosis, for example, by diagnosing a unit that could not be diagnosed during operation (daytime) of a factory at night.

According to the embodiment of the present invention described above, the following operational effects are obtained.

(1) A power conversion unit diagnosis system according to the present invention includes: a plurality of power conversion units each of which includes an input unit that receives alternating-current (AC) power from an AC power supply, and an output unit that converts the AC power into direct-current (DC) power and outputs the DC power, supplies the DC power to at least one load, and each of the plurality of power conversion units being connected in series to the AC power supply; a control unit that controls the plurality of power conversion units; and an output-side switching unit capable of connecting the output units of at least some of the plurality of power conversion units among the plurality of power conversion units to one of the loads in parallel, in which the control unit determines a state of each of the plurality of power conversion units when the output units of the at least some of the plurality of power conversion units are connected in parallel to the one load and compares the determined states of the plurality of power conversion units to diagnose whether or not the characteristics of each of the plurality of power conversion units have deteriorated.

With the above configuration, in a case where a plurality of power conversion units are operated simultaneously, it is possible to individually determine each characteristic change. Therefore, it is possible to appropriately adjust the control of the deteriorated unit based on the characteristic change and to extend the life time of the unit.

(2) The power conversion unit includes a power semiconductor element and a capacitor, and a state of the power conversion unit is a change in thermal resistance of the power semiconductor element and a change in temperature of the capacitor. These states directly lead to deterioration of the power conversion unit, but can be easily measured by an existing temperature sensor or the like, so that the degree of deterioration of the power conversion unit can also be easily determined.

(3) The control unit controls the power conversion unit to suppress the change in thermal resistance of the power semiconductor element and/or the change in temperature of the capacitor with respect to the power conversion unit whose characteristics are determined to be deteriorated. More specifically, the control unit reduces a fluctuation range of power output from the power conversion unit in order to suppress the change in thermal resistance of the power semiconductor element and sets a time during which power is not output from the power conversion unit in order to suppress the change in temperature of the capacitor. As a result, for example, the effect of the present invention can be easily obtained only by adjusting the control signal supplied to the power conversion unit.

(4) The power conversion unit diagnosis system further includes an input-side switching unit that switches parallel connection between the input units of the plurality of power conversion units, in which when the plurality of power conversion units are connected in parallel by the input-side switching unit, output units of the plurality of power conversion units are connected to a single DC power supply. As described above, since it is not necessary to operate the AC power supply, it is possible to diagnose the state of the unit in a self-contained manner when it is not necessary to supply power to another load (for example, at night when a factory in which the load is installed does not operate, or the like), which is preferable in terms of efficiency and cost.

Note that the present invention is not limited to the above embodiments, and various modifications are possible. For example, the above-described embodiments have been described in detail in order to describe the present invention in an easy-to-understand manner, and the present invention is not necessarily limited to an aspect including all the described configurations. Further, a part of the configuration of one embodiment can be replaced with the configuration of another embodiment. In addition, the configuration of another embodiment can be added to the configuration of a certain embodiment. In addition, a part of the configuration of each embodiment can be deleted, or another configuration can be added or replaced.

### REFERENCE SIGNS LIST

1 AC power supply
10a to 10c power conversion unit
11a to 11c power semiconductor element
12a to 12c smoothing capacitor
20 power conversion unit controller (control unit)
40 output-side switching unit
51, 53 load
60 input-side switching unit
100 power conversion unit diagnosis system

1. A power conversion unit diagnosis system comprising:
a plurality of power conversion units each of which includes an input unit that receives alternating-current (AC) power from an AC power supply, and an output unit that converts the AC power into direct-current (DC) power and outputs the DC power, supplies the DC power to at least one load, and each of the plurality of power conversion units being connected in series to the AC power supply;
a control unit that controls the plurality of power conversion units; and
an output-side switching unit capable of connecting the output units of at least some of the plurality of power conversion units among the plurality of power conversion units to one of the loads in parallel,
wherein the control unit determines a state of each of the plurality of power conversion units when the output units of the at least some of the plurality of power conversion units are connected in parallel to the one load and compares the determined states of the plurality of power conversion units to diagnose whether or not the characteristics of each of the plurality of power conversion units have deteriorated.

2. The power conversion unit diagnosis system according to claim 1, wherein
the power conversion unit includes a power semiconductor element and a capacitor, and
a state of the power conversion unit is a change in thermal resistance of the power semiconductor element and a change in temperature of the capacitor.

3. The power conversion unit diagnosis system according to claim 2, wherein
the control unit controls the power conversion unit to suppress the change in thermal resistance of the power semiconductor element and/or the change in temperature of the capacitor with respect to the power conversion unit whose characteristics are determined to have deteriorated.

4. The power conversion unit diagnosis system according to claim 3, wherein
the control unit reduces a fluctuation range of power output from the power conversion unit in order to suppress the change in thermal resistance of the power semiconductor element and sets a time during which power is not output from the power conversion unit in order to suppress the change in temperature of the capacitor.

5. The power conversion unit diagnosis system according to claim 1, further comprising
an input-side switching unit that switches parallel connection between the input units of the plurality of power conversion units,
wherein, when the plurality of power conversion units are connected in parallel by the input-side switching unit, output units of the plurality of power conversion units are connected to a single DC power supply.
